(19) United States
(12) Patent Application Publication
(10) Pub. No.: US 2009/0147462 A1
(43) Pub. Date: Jun. 11, 2009

(54) Device for enclosing a flash memory module

(75) Inventors: Zhi-Wen Zhu, Kunshan (CN); Jin-Kui Hu, Kunshan (CN)

Correspondence Address: WEI TE CHUNG;FOXCONN INTERNATIONAL, INC., 1650 MEMOREX DRIVE, SANTA CLARA, CA, 95050, US

(73) Assignee: HON HAI PRECISION IND. CO., LTD.

(21) Appl. No.: 12/316,326

(22) Filed: Dec. 11, 2008

(30) Foreign Application Priority Data
Dec. 11, 2007 (CN) 200720131352.6

(51) Int. Cl. H05K 5/00

(52) U.S. Cl. 361/679.31

(57) ABSTRACT

A device (100) for enclosing a flash memory module includes a first shell (1) having a groove (13), and an outer wall (14) covering the groove and having an reduced opening (142) communicating with the groove. An attachment mechanism (4) coupled to the first shell comprises a retaining member (42) having a base portion (421) retained in the groove and an engaging portion (422) extending from the base portion and through the opening outwardly, and a ring (41) coupled to the engaging portion of the retaining member. The base portion is abutted against by the outer wall.

### BACKGROUND OF THE INVENTION

1. Field of the Invention

The present invention generally relates to a device for enclosing a flash memory module and more particularly to a portable device which has a attachment mechanism.

2. Description of Related Art

A conventional flash memory device is widely used by consumers as an intermedium for accessing data files from one device to another, or like a portable hard drive for installing materials. Usually, the flash memory device includes a flash memory module having a circuit board for saving or loading data and a plug connected to one end of the circuit board, a device for enclosing the flash memory module. The device includes a second shell for enclosing the circuit board, a first shell coupled to the second shell and enclosing the plug, and an attachment mechanism coupled to the first shell. The attachment mechanism has a pair of retaining member retained in holes at a rear end of the first shell and a ring having two ends attached to the retaining members. Therefore, the attachment mechanism makes the flash memory device portable.

However, the retaining members of the attachment mechanism are inserted into the holes directly along a front-rear end of the first shell at a predetermined angle, the retaining members are easily loosen from the holes after the use of the device over a long period of time.

Hence, an improvement over the prior art is required to overcome the problems thereof.

### SUMMARY OF THE INVENTION

According to one aspect of the present invention, a device for enclosing a flash memory module comprises a first shell having a groove, and an outer wall covering the groove and having an reduced opening communicating with the groove. An attachment mechanism coupled to the first shell comprises a retaining member having a base portion retained in the groove and an engaging portion extending from the base portion and through the opening outwardly, and a ring coupled to the engaging portion of the retaining member. The base portion is abutted against by the outer wall.

According to another aspect of the present invention, a device for enclosing a flash memory module comprises a first shell having a pair of openings at two lateral sides thereof, and a pair of enlarged grooves inside the openings and communicating with the openings. An attachment mechanism coupled to the first shell comprises a pair of retaining members each having a base portion retained in the groove and an engaging portion extending from the base portion and through the opening outwardly, and a ring coupled to the engaging portions of the retaining members. The base portion is wider than the opening along a height direction of the first shell.

These and additional objects, features, and advantages of the present invention will become apparent after reading the following detailed description of the preferred embodiment of the invention taken in conjunction with the appended drawings.

### BRIEF DESCRIPTION OF THE DRAWINGS

FIG. 1 is a perspective view of a device for enclosing a flash memory module according to the present invention;

FIG. 2 is a partly exploded view of the device shown in FIG. 1;

FIG. 3 is an another partly exploded view of the device shown in FIG. 1;

FIG. 4 is an exploded view of the device shown in FIG. 1;

FIG. 5 is an another exploded view of the device shown in FIG. 1;

FIG. 6 is a perspective view of a retaining member coupled to a first shell of the device shown in FIG. 1; and

FIG. 7 is an exploded enlarged view of the first shell of the device shown in FIG. 1.

### DETAILED DESCRIPTION OF THE INVENTION

Reference will now be made to the drawing figures to describe the preferred embodiment of the present invention in detail.

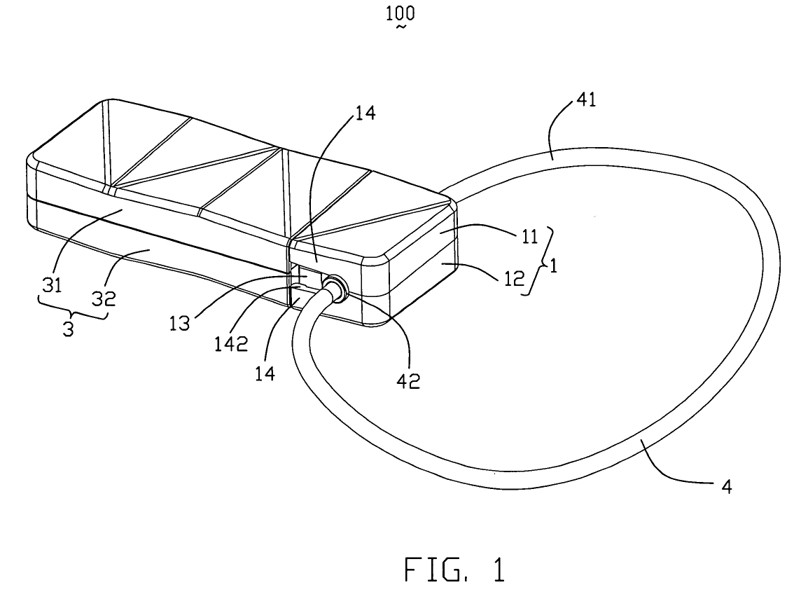

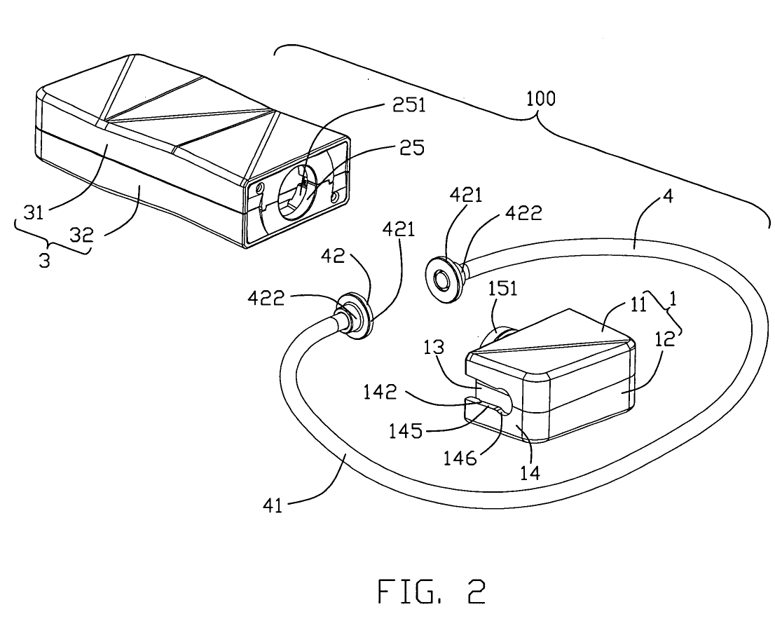

Referring to FIGS. 1 and 2, the device 100 for enclosing a flash memory module (not shown) according to the present invention includes a first shell 1, a second shell 2 for enclosing the flash memory module, a third metal shell 3 enclosing the second shell 2 and an attachment mechanism 4 coupled to the first shell 1. the flash memory module is coupled with a plurality of electronic components, such as driver chip, memory chip, oscillator, resistor; etc, for saving and loading data, functioning as a miniature hard drive, and having a plug at one end thereof.

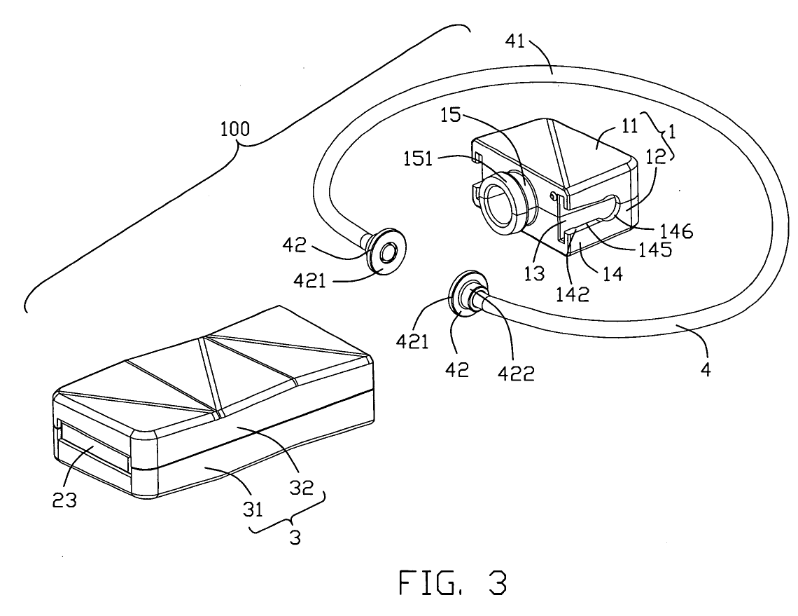

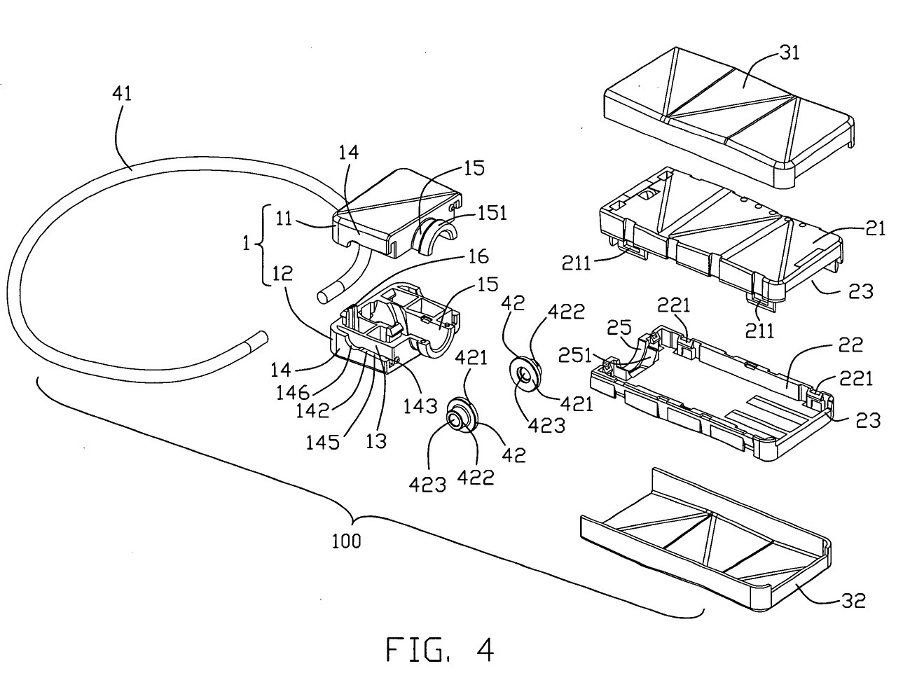

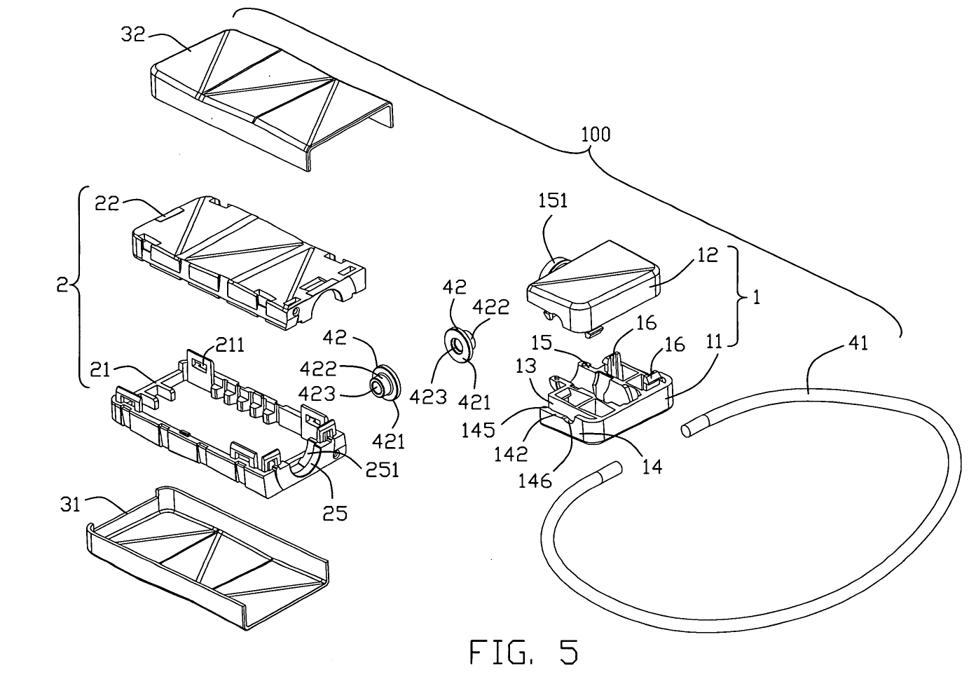

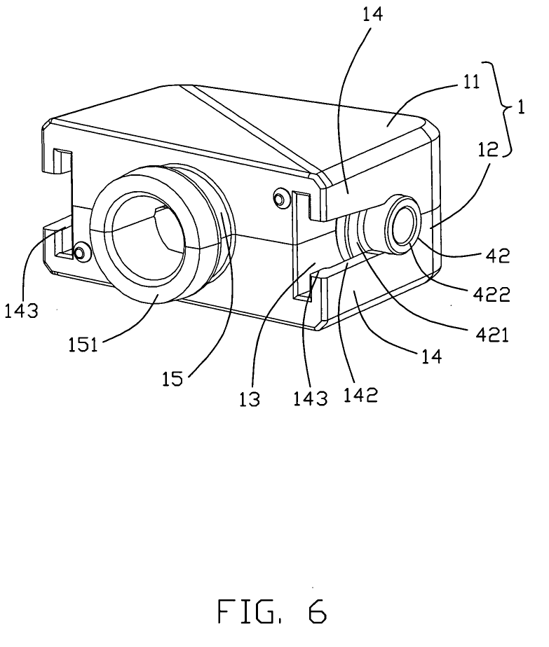

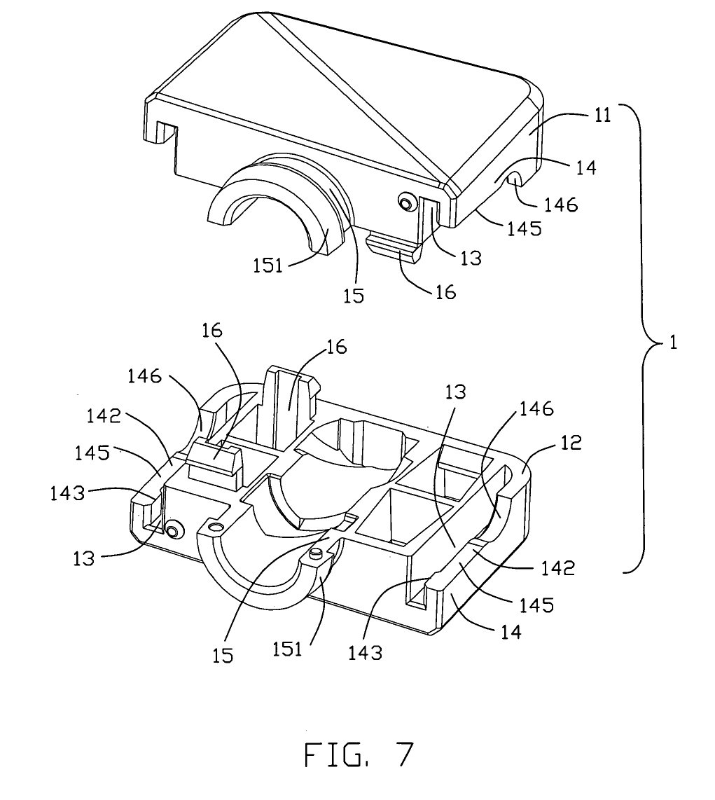

Referring to FIGS. 3-7, the first shell 1 has a pair of grooves 13 at two lateral sides thereof and a pair of outer walls 14 covering the corresponding grooves 13. Each outer wall 14 has an reduced opening 142 which is narrower than the groove 13 along a height direction of the first shell 1 and communicating with the groove 13. The opening 142 has a sliding opening 145 at a front portion thereof and extending through a front end of the outer wall 14, and an enlarged receiving opening 146 which is wider than the sliding opening 145 along a height direction of the first shell 1 behind the sliding opening 145 and communicating with the sliding opening 145. Each outer wall 14 has a pair of projections 143 at a front end of the sliding opening 145 and protruding into the corresponding groove 13. The first shell 1 has a spindle 15 integrally extending at a front end thereof. The spindle 15 has a flange 151 formed around a front portion thereof. The first shell 1 includes a first upper shell 11 and a first lower shell 12 each has a plurality of barbs 16 for latching onto each other.

The second shell 2 has a interface 23 at a front end thereof for the plug coming out therefrom and a circular hole 25 at a rear end thereof for rotatablely receiving the spindle 15 therein. Therefore, the first shell 1 could be rotated with respective to the second shell 2. The circular hole 25 has a depression 251 formed on a front end thereof for receiving the flange 151. the flange 151 has a larger diameter than the circular hole 25 so as to retain the first shell 1 in the second shell 2. The second shell 2 includes a second upper shell 21 having a plurality of apertures 211 and a second lower shell 22 having a plurality of locking protrusions 221 locked with the apertures 211.

The third metal shell 3 includes a third upper metal shell 31 enclosing the second upper shell 21 and a third lower metal shell 32 enclosing the second lower shell 22. Therefore, the third metal shell 3 could make the device 100 firm and prevent Electro-Magnetic Interference (EMI).

The attachment mechanism 4 includes a pair of retaining members 42 coupled to the first shell 1 and a ring 41 couple to the retaining members 42. The ring 41 could be a wire cord or a metal chain. Each retaining member 42 includes a base portion 421 received in the groove 13 and an engaging portion 422 extending integrally from the base portion 421. Both the base portion 421 and the engaging portion 422 are present as columned shapes. The engaging portion 422 has a smaller diameter than that of the base portion 421. In another alternative embodiment according to the invention, the base portion 421 and the engaging portion 422 could be present as quadrate shapes. The retaining member 42 has a through hole 423 going through the base portion 421 and the engaging portion 422. The ring 41 has two ends retained in the through hole 423.

When assembling the retaining members 42 into the first shell 1, rotate the first shell 1 at a predetermined angle with respect to the second shell 2, so that a front end of the groove 13 is exposed to external, the engaging portion 422 and the base portion 421 of each retaining member 42 slide from the sliding opening 145 and the front end of the groove 13 into the receiving opening 146 and a rear end of the groove 13. The sliding opening 145 is slightly narrower than the engaging portion 422 to produce a tight fit therebetween. When the retaining member 42 slide into the groove 13 completely, the engaging portion 422 extending through the receiving opening 146 outwardly, the outer wall 14 abuts against the base portion 421, the sliding opening 145 which is slightly narrower than the engaging portion 422 make sure the retaining member 42 hardly to slide forwardly into the sliding opening 145, and the projections 143 in the outer wall 14 could have an interfering engagement with the base portion 41 when the base portion 41 slides forwardly out from the sliding opening 145. So the retaining members could be retained into the grooves 13 firmly. Furthermore, the attachment mechanism 4 could be removed from the first shell 1 under a condition that the retaining members 42 are pulled forwardly out from the openings 14 and the grooves via an external force.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A device for enclosing a flash memory module, comprising:
a first shell having a groove, and an outer wall covering the groove and having an reduced opening communicating with the groove; and
an attachment mechanism comprising a retaining member having a base portion retained in the groove and an engaging portion extending from the base portion and through the opening outwardly, and a ring coupled to the engaging portion of the retaining member, the base portion being abutted against by the outer wall.

2. The device for enclosing a flash memory module as claimed in claim 1, wherein the retaining member has a through hole going through the base portion and the engaging portion, said ring has an end retained in the through hole.

3. The device for enclosing a flash memory module as claimed in claim 1, wherein the opening has a sliding opening extending through a front end of the outer wall into which the engaging portion slides, and an enlarged receiving opening behind the sliding opening and communicating with the sliding opening for retaining the engaging portion therein.

4. The device for enclosing a flash memory module as claimed in claim 3, wherein the outer wall has a pair of projections at a front end of the sliding opening and protruding into the groove for interfering engagement with the base portion.

5. The device for enclosing a flash memory module as claimed in claim 1, wherein the base portion and the engaging portion both are present as columned shapes, the engaging portion has a smaller diameter than that of the base portion.

6. The device for enclosing a flash memory module as claimed in claim 1, wherein the device comprises a second shell defining a circular hole on a rear end thereof, the first shell has a spindle on a front end and rotatablely received in the circular hole.

7. The device for enclosing a flash memory module as claimed in claim 6, wherein the spindle has a flange formed around a front portion thereof, the circular hole has a depression formed on a front end thereof for receiving the flange.

8. The device for enclosing a flash memory module as claimed in claim 6, wherein the second shell comprises a second upper shell defining a plurality of apertures and a second lower shell defining a plurality of locking protrusions locked with the apertures.

9. The device for enclosing a flash memory module as claimed in claim 8, wherein further comprises a third metal shell having a third upper metal shell enclosing the second upper shell and a third lower metal shell enclosing the second lower shell.

10. The device for enclosing a flash memory module as claimed in claim 1, wherein the first shell has a first upper shell and a first lower shell each has a plurality of barbs for latching onto each other.

11. A device for enclosing a flash memory module, comprising:
a first shell having a pair of openings at two lateral sides thereof, and a pair of enlarged grooves inside the openings and communicating with the openings; and
an attachment mechanism comprising a pair of retaining members each having a base portion retained in the groove and an engaging portion extending from the base portion and through the opening outwardly, and a ring coupled to the engaging portions of the retaining members, the base portion being wider than the opening along a height direction of the first shell.

12. The device for enclosing a flash memory module as claimed in claim 11, wherein each retaining member has a through hole going through the base portion and the engaging portion, said ring has two ends retained in the through holes of the two retaining member.

13. The device for enclosing a flash memory module as claimed in claim 12, wherein the base portion and the engaging portion both are present as columned shapes, the engaging portion has a smaller diameter than that of the base portion.

14. The device for enclosing a flash memory module as claimed in claim 11, wherein the opening having a sliding opening into which the engaging portion slides, and a enlarged receiving opening behind the sliding opening and communicating with the sliding opening for retaining the engaging portion therein.

15. The device for enclosing a flash memory module as claimed in claim 14, wherein the first shell has a pair of projections at a front end of the sliding opening and protruding into the groove for interfering engagement with the base portion.

16. A device for enclosing a flash memory module, comprising:
a first shell assembled to a second shell via a shaft structure so as to allow the first shell to be rotatable with regard to the second shell about an axis along said shaft;
a pair of slots formed in two side faces of the first shell and having an open end terminating at an interface of edge of the first shell neighboring with the second shell;
a band linked to the first shell via a pair of retaining members located by two opposite ends of the band and retainably received in the corresponding slots; wherein
the open end of the slot is blocked by the second shell when said first shell and said second shell are oriented with each other in a coplanar manner for no removal of retaining member from the corresponding slot of the first shell, while is open to an exterior when in an angular manner for removal of the retaining member from the corresponding slot of the first shell.

17. The device as claimed in claim 16, wherein said first shell and said second shell are of a similar circumferential contour in a cross-sectional view for obtaining a compliant exterior shape of the whole device.
